(19) United States
(12) Patent Application Publication
(10) Pub. No.: US 2013/0025657 A1
(43) Pub. Date: Jan. 31, 2013

(54) PLASMON ENHANCED DYE-SENSITIZED SOLAR CELLS

(71) Applicants: Jifa Qi, West Roxbury, MA (US); Xiangnan Dang, Cambridge, MA (US); Angela M. Belcher, Lexington, MA (US); Paula T. Hammond, Brookline, MA (US)

(72) Inventors: Jifa Qi, West Roxbury, MA (US); Xiangnan Dang, Cambridge, MA (US); Angela M. Belcher, Lexington, MA (US); Paula T. Hammond, Brookline, MA (US)

(21) Appl. No.: 13/560,422

(22) Filed: Jul. 27, 2012

Related U.S. Application Data
(60) Provisional application No. 61/512,064, filed on Jul. 27, 2011.

(51) Int. Cl. H01L 31/072; H01L 31/18; B82Y 15/00; B82Y 40/00

(52) U.S. Cl. 136/255; 438/85; 257/E31.032; 977/948; 977/890

(57) ABSTRACT

A dye-sensitized solar cell can include a plurality of a plasmon-forming nanostructures. The plasmon-forming nanostructures can include a metal nanoparticle and a semiconducting oxide on a surface of the metal nanoparticle.

### CLAIM OF PRIORITY

This application claims priority to provisional U.S. application No. 61/512,064, filed Jul. 27, 2011, which is incorporated by reference in its entirety.

### TECHNICAL FIELD

The present invention generally relates to plasmon enhanced dye-sensitized solar cells.

### BACKGROUND

The need for preserving non-renewable energy and lowering carbon dioxide emission requires efficient and inexpensive approaches to utilize solar energy. Dye-sensitized solar cells (DSSCs) are a promising technology due to their low cost and potentially higher efficiency than silicon solar cells. DSSCs offer high internal quantum efficiency, large surface-to-volume ratio, and a tunable absorption range.

### SUMMARY

In one aspect, a dye-sensitized solar cell includes a photoanode including a plurality of TiO₂ nanoparticles and a plurality of a plasmon-forming nanostructures, where each plasmon-forming nanostructure includes a metal nanoparticle and a semiconducting oxide on a surface of the metal nanoparticle.

In another aspect, a method of generating solar power includes illuminating a dye-sensitized solar cell including a photoanode including a plurality of TiO₂ nanoparticles and a plurality of a plasmon-forming nanostructures, where each plasmon-forming nanostructure includes a metal nanoparticle and a semiconducting oxide on a surface of the metal nanoparticle. Each plasmon-forming nanostructure can include a core including the metal nanoparticle.

Each plasmon-forming nanostructure can include a coating on the core, where the coating includes the semiconducting oxide. The metal nanoparticle can include silver or gold. The semiconducting oxide can include TiO₂. The core can have a diameter of no greater than 50 nm. The coating can have a thickness of no greater than 5 nm. The plurality of plasmon-forming nanostructures can be interspersed with the plurality of TiO₂ nanoparticles. The plasmon-forming nanostructures can be 0.01 wt % to 2.5 wt % of the total nanoparticles in the photoanode.

In another aspect, a method of making a dye-sensitized solar cell includes forming a photoanode including a plurality of TiO₂ nanoparticles and a plurality of a plasmon-forming nanostructures, where each plasmon-forming nanostructure includes a metal nanoparticle and a semiconducting oxide on a surface of the metal nanoparticle.

Forming the photoanode can include depositing the plurality of plasmon-forming nanostructures on a substrate. Forming the photoanode can include mixing the plurality of TiO₂ nanoparticles with the plurality of plasmon-forming nanostructures prior to depositing.

Other aspects, embodiments, and features will become apparent from the following description, the drawings, and the claims.

### BRIEF DESCRIPTION OF THE DRAWINGS

FIG. 1 is a schematic depiction of a dye-sensitized solar cell.

FIG. 2 is a schematic depiction of plasmon-forming nanoparticles.

FIG. 3 illustrates device structures of conventional DSSCs (FIG. 3A) and plasmon-enhanced DSSCs (FIG. 3B). FIGS. 3C-3D illustrate photo-generated electron collection in conventional DSSCs (FIG. 3C) and plasmon-enhanced DSSCs (FIG. 3D). FIGS. 3E-3F illustrate mechanisms of plasmon-enhanced DSSCs using Ag@TiO₂ nanoparticles (FIG. 3E) and Ag nanoparticles (FIG. 3F).

FIGS. 4A-4C are TEM and HRTEM images of Ag@TiO₂ nanoparticles. FIG. 4D shows optical absorption spectra of solutions of Ag nanoparticles stabilized by PVP (molecular weight 10,000 D), TiO₂ nanoparticles and Ag@TiO₂ nanoparticles.

FIG. 5 shows XRD patterns of Ag@TiO₂ nanoparticles as-synthesized at room temperature (FIG. 5A) and after annealing at 500° C. for 30 minutes (FIG. 5B). The inverted triangle symbols indicate the XRD patterns from anatase structured TiO₂. FIGS. 5C-5D show the XRD patterns based on the JCPDS card for anatase TiO₂ (#21-1272) and Ag (#04-0783), respectively.

FIG. 6 is a series of graphs demonstrating LSP induced enhancement of optical absorption of dye molecules in solution and thin film. FIG. 6A shows optical absorption spectra of Ag nanoparticles, ruthenium dye molecules, and their mixture in ethanol solution. FIG. 6B shows net changes of dye absorption (ΔOD) due to the presence of Ag nanoparticles in solution. FIG. 6C shows relative changes of effective extinct coefficient of dye (Δα/α) due to the presence of Ag nanoparticles in solution. FIG. 6D shows optical absorption spectra of Ag@TiO₂ nanoparticles, ruthenium dye molecules, and their mixtures (immediately after mixing and 16 hours after mixing) in ethanol solution. FIG. 6E shows net changes of dye absorption (ΔOD) due to the presence of Ag@TiO₂ nanoparticles in solution. FIG. 6F shows relative changes of effective extinct coefficient of dye (Δα/α) due to the presence of Ag@TiO₂ nanoparticles in solution. FIG. 6G shows optical absorption spectra of Ag@TiO₂ nanoparticles, ruthenium dye molecules, and their mixtures in the matrix of a TiO₂ thin film. FIG. 6H shows net changes of dye absorption (ΔOD) due to the presence of Ag@TiO₂ nanoparticles in thin film. FIG. 6I shows relative changes of effective extinct coefficient of dye (Δα/α) due to the presence of Ag@TiO₂ nanoparticles in thin film. For the calculation of ΔOD and Δα/α: Δα/α=ΔOD(λ)/OD_{dye}(λ)=(OD_{dye,Ag}(λ)−OD_{dye}(λ)−OD_{Ag}(λ))/OD_{dye}(λ), where OD_{dye}(λ), OD_{Ag}(λ) and OD_{dye,Ag}(λ) are the optical densities at wavelength λ of pure dye solution, Ag nanoparticle solution and their mixture solution with the same concentrations of dye and Ag nanoparticles, respectively. For the solid state thin films, the net absorption of dye molecule is OD_{dye}(λ)=OD_{dye,TiO2}(λ)−OD_{TiO2}(λ),

FIG. 7 shows the effect of LSP on the performance of DSSCs. FIG. 7A is a graph showing current density and PCE of the plasmon-enhanced DSSC (Ag/TiO₂=0.6 wt %, η=4.4%, FF=66%) and TiO₂-only DSSC (η=3.1%, FF=64%) with the same photoanode thickness of 1.5 μm. FIGS. 7B-7C show the dependence of PCE and J_{SC} on the concentration of Ag@TiO₂ nanoparticles in photoanodes with the same thickness of 1.5 μm. FIG. 7D shows the PCE of plasmon-enhanced DSSC and TiO₂-only DSSC with photoanodes of different thickness, where the lines are drawn to show the trend. FIG. 7E shows current density and PCE of the most efficient plasmon-enhanced DSSC (Ag/TiO₂=0.1 wt %, η=9.0%, FF=67%, 15 μm) and TiO₂-only DSSC (η=7.8%, FF=66%, 20 μm) in this work.

FIGS. 8A-8B are graphs showing spectral responses of TiO₂-only and plasmon-enhanced DSSCs. FIG. 8A is an IPCE spectra of DSSCs with and without the presence of Ag@TiO₂. FIG. 8B shows the relative change of the IPCE caused by the incorporation of Ag@TiO₂ nanoparticles. ΔIPCE/IPCE(λ)=(IPCE_{plasmon-enhance}(λ)−IPCE_{TiO2-only}(λ))/IPCE_{TiO2-only}(λ), where IPCE_{plasmon-enhanced}(λ) and IPCE_{TiO2-only}(λ) are the ICPE at wavelength λ for plasmon-enhanced DSSC and TiO₂-only DSSC, respectively.

### DETAILED DESCRIPTION

Dye-sensitized solar cells (DSSCs) have attracted great attention for high power conversion efficiency (PCE) and the low cost of materials and fabrication processes.¹⁻⁵

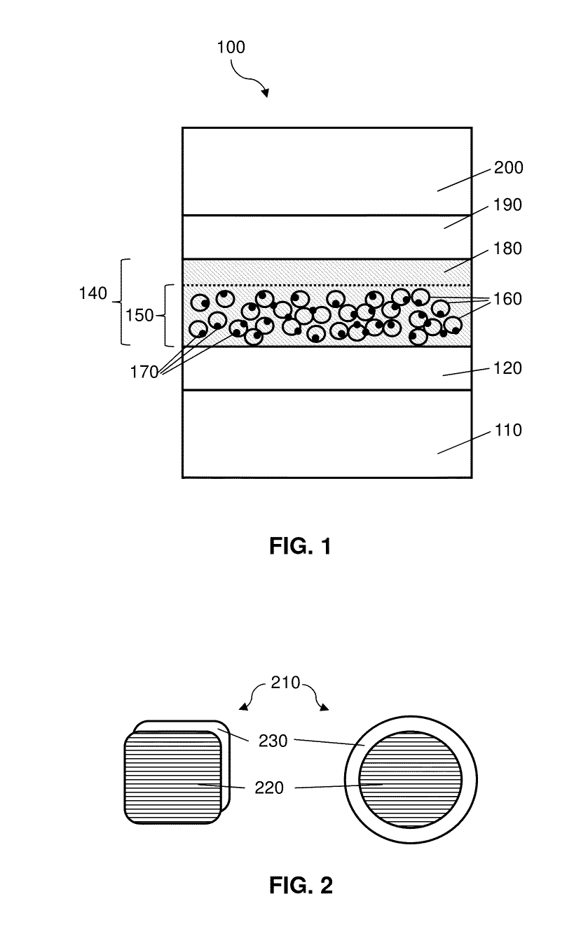

With reference to FIG. 1, solar cell 100 includes substrate 110 (e.g., glass) which supports current collector 120. Current collector 120 is proximate to photoanode 140 such that current can flow between photoanode 140 and current collector 120. Photoanode 140 can be a porous layer. Photoanode 140 can include porous layer 150 of a photoanode material. The photoanode material include nanoparticles 160 of the photoanode material. The nanoparticles can be dispersed within a matrix. Nanoparticles 160 can be discrete nanoparticles, or can be interconnected by the matrix (which may also include or be made of the photoanode material), or the nanoparticles can include a mixture of discrete and interconnected nanoparticles. a combination of the two. Porosity in layer 150 can exist between and among nanoparticles 160. Light absorbing dye 170 is optionally adsorbed and/or covalently bound on the photoanode material. FIG. 1 illustrates dye 170 adsorbed to nanoparticles 160.

Photoanode 140 also includes electrolyte 180. Electrolyte 180 is in contact with, and can be suffused through, the porosity of porous layer 150. Electrolyte 180 is also in contact with conductive layer 190 (i.e., the cathode). Conductive layer 190 can be, for example, a layer of Pt. Conductive layer 190 is covered by cover layer 200, which is transparent, e.g., glass.

Composite materials, such as nanocomposite materials, can provide advantageous properties that non-composite materials cannot. For example, nanocomposites including plasmon-forming nanostructures can be useful in a variety of applications, including optoelectronic devices, such as light emitting devices, and photovoltaics, e.g., dye-sensitized solar cells. Metal nanoparticles, with an optional semiconducting oxide on the surface of the metal nanoparticle, can be plasmon-forming nanostructures.

To improve the PCE of DSSCs, conventional approaches include enhancing absorption of incident light^{2, 5} and improving collection of photo-generated carriers.^{6, 7} By changing thickness or morphology^{6, 7} of the photoanode, the light absorption and carrier collection, however, is often affected in opposite ways. Effort has also been devoted to developing new dyes⁸⁻¹⁰ and using semiconductor quantum dots.^{11, 12} Nevertheless, employing new dyes or quantum dots could change the adsorption of the sensitizers on TiO₂, as well as their energy band positions relative to the conduction band of TiO₂ and the redox potential of electrolyte, affecting charge separation. Therefore, improving light harvest or carrier collection without affecting other factors has been considered a more effective approach to improve device performance.¹³ Localized surface plasmon (LSP) has potential for improving performance of DSSCs for the unique capability to improve the light absorption of dye with minimal impact on other material properties.

Generally, there are three types of plasmonic light-trapping geometries,¹⁴ including far-field scattering, near-field LSP, and surface plasmon polaritons at the metal/semiconductor interface (see, e.g., Atwater, H. A.; Polman, A., Nature Mater. 2010, 9, 205-213, which is incorporated by reference in its entirety). Surface plasmon arising from metal nanoparticles has been applied to increase the optical absorption and/or photocurrent in a wide range of solar cell configurations, e.g., silicon solar cells, organic solar cells,¹⁹⁻²¹ organic bulk heterojunction solar cells,²² CdSe/Si heterostructures²³ and DSSCs.²⁴⁻³² However, work on plasmon-enhanced DSSCs has reported improved dye absorption or photocurrent, while improved device performance was not observed.²⁴⁻²⁸ In addition, earlier plasmonic geometries contained metal nanoparticles in direct contact with the dye and the electrolyte,^{24-26, 29, 30} resulting in recombination and back reaction of photo-generated carriers and corrosion of metal NPs by electrolyte.

Recently, core-shell Au@SiO₂ nanoparticles have been used to enhance PCE by preventing carrier recombination and back reaction.³² However, by using an insulating shell, some of the photo-generated carriers from the most absorption-enhanced dye molecules located on the surfaces of SiO₂ are lost, due to the difficulty in the injection to SiO₂.

With reference to FIGS. 1 and 2, photoanode 140 can further optionally include nanostructures 210. FIG. 2 illustrates two configurations of nanostructures; features of these configurations may be found in various combinations as explained below. nanostructures 210 can be plasmon-forming nanostructures. nanostructures 210 can be composite nanostructures, i.e., including two or more different materials in a single nanostructure. nanostructures 210 can include a metal nanoparticle 220 and an oxide 230 on a surface of the metal nanoparticle. Metal nanoparticle 220 can be, for example, Ag, Au, or a combination of these. Oxide 230 can be a semiconducting oxide, such as, for example, TiO₂.

Metal nanoparticle 220 can have any of a variety of shapes, including spherical, oblate, elongated, rod-shaped, wire-shaped, cubic, tetrahedral, octahedral, or another regular or irregular shape. A combination of metal nanoparticles having different shapes can be used. Metal nanoparticles having various shapes, and methods for making these, are known in the art. Methods for formation of an oxide on a surface of a metal nanoparticle are also known. Oxide 230 can partially (as shown on the left of FIG. 2) or substantially fully (as shown on the right) coat the metal nanoparticle 220. Nanoparticles 210 can be referred to as “M@oxide nanoparticles,” simply as “M@oxide,” or “core-shell nanoparticles,” when they include a metal (M) nanoparticle 220 which is substantially fully coated by oxide 230. For example, a silver metal nanoparticle 220 substantially fully covered by TiO₂ can be referred to as an Ag@TiO₂ nanoparticle, or simply Ag@TiO₂.

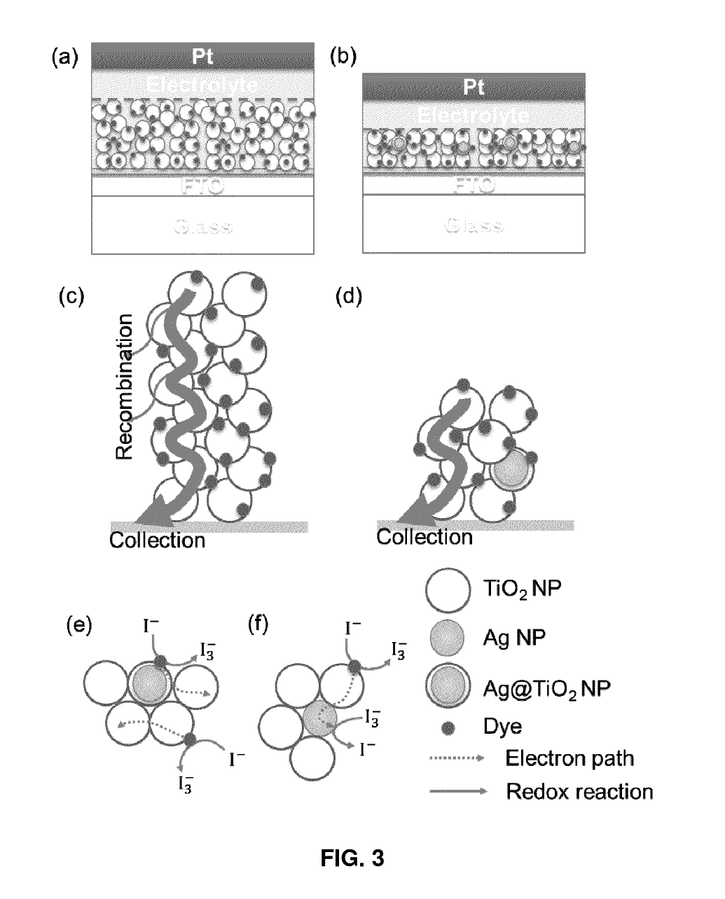

In some instances, oxide 230 can include or be made of the same material(s) as found in the photoanode material, e.g., the material(s) that are found in or make up nanoparticles 160, or the material(s) that are found in or make up the optional matrix in which nanoparticles 160 are dispersed. For example, photoanode 140 can includes a TiO₂ matrix in which TiO₂ nanoparticles 160 can be dispersed. Optionally, plasmon-forming nanoparticles 210 where oxide 230 is TiO₂ are also dispersed in the TiO₂ matrix. In this regard, see also FIGS. 3A and 3B.

When the oxide is a semiconducting oxide, carriers can be more readily transferred to the photoanode material than if the oxide is an insulator. This transfer can be particularly facilitated when both the semiconducting oxide and the photoanode material include TiO₂. The size of the metal nanoparticle can small, e.g., having a diameter of no greater than 200 nm, no greater than 150 nm, no greater than 100 nm, no greater than 50 nm, no greater than 40 nm, no greater than 30 nm, or less. The oxide on the surface of the metal nanoparticle can be thin, e.g., no greater than 20 nm thick, no greater than 10 nm thick, no greater than 5 nm thick, or less.

Porous layer 150 can be made by first preparing a population of nanoparticles of a photoanode material, e.g., TiO₂, followed by a spin-casting procedure to deposit the nanoparticles over a current collector. For porous layers including nanoparticles 210, a population of plasmon-forming nanoparticles (e.g., a population of M@oxide nanoparticles) can be formed separately. The photoanode nanoparticles and the plasmon-forming nanoparticles can be combined in a desired ratio prior to depositing over the current collector. The desired ratio can be measured with regard to wt % of the plasmon-forming nanoparticles in the total combined population of nanoparticles prior to depositing. Once the combined population has been formed, porous layer 150 can be made with the combined population according to conventional procedures.

DSSCs incorporating the nanostructures can have a PCE greater than comparable DSSCs which lack the nanostructures, particularly for DSSCs having thin photoanodes (e.g., no greater than 20 μm thick, no greater than 15 μm thick, no greater than 10 μm thick, no greater than 5 μm thick, or thinner). The DSSC can have increased efficiency when the nanostructures are present in only a small amount (e.g., no greater than 5 wt %, no greater than 2 wt %, or no greater than 1 wt %, relative to the amount of photoanode material). Furthermore, that increased efficiency can be achieved with a thinner photoanode than a comparable DSSC which lacks the nanostructures. A thinner photoanode can provide more effective electron collection within the device. The DSSCs including the nanostructures can achieve similar levels of efficiency as those lacking the nanostructures, while requiring less material in construction.

### EXAMPLES

Materials. Titanium iso-propoxide (TPO, 97%) and polyvinylpyrrolidone with an average molecular weight of 10 kg/mol (PVP-10) were purchased from Sigma-Aldrich; ethanol (99.5%), acetone (99.5%), nitric acid (70%) and ethylene glycol (99.9%) were purchased from Mallinckrodt Chemicals; ammonia (28-30 wt % NH₃ in water) was purchased from VWR International Inc. Cis-bis(isothiocyanato)bis(2,2′-bipyridyl-4,4′-dicarboxylato)-ruthenium(II) (also called N3 or Ruthenizer 535, purchased from Solaronix) was used as 0.5 mM solution in acetonitrile and tert-butanol (volume ratio=1:1). All chemicals were used as received. All water was deionized (18.2 MΩ, milli-Q pore).

Synthesis of nanoparticles. TiO₂ nanoparticles (20 nm sized) were synthesized using procedures in the literature⁵. Small Ag nanoparticles with a diameter of 20-30 nm were synthesized by a modified polyol process: typically, 0.1 mmol of silver nitrate was added to 25 mL of ethylene glycol solution containing 0.5 g of PVP-10, and the mixture was kept stiffing at room temperature until silver nitrate was completely dissolved. Then the solution was slowly heated up to 120° C. and kept at the temperature for 1 hour with constant stirring. After the reaction, the nanoparticles were separated from ethylene glycol by addition of acetone (200 mL of acetone per 25 mL of reaction mixture) and subsequent centrifugation at 3000 rpm. The supernatant was removed and the NPs were washed with ethanol and centrifuged at 3000 rpm, and redispersed in a solution of 4% ammonia in ethanol (achieved by diluting the 28% ammonia 7 times in ethanol). This solution was directly used for coating TiO₂ shell by adding TPO solution in ethanol. The total amount of TPO added depended on the desired thickness of the TiO₂ shell. Typically, 6 μl of TPO in 1 ml of ethanol was added into the solution, yielding a shell of TiO₂ around 2 nm thick. The reaction mixture was then stirred for 12 hours at room temperature in the dark.

Both the Ag nanoparticles in ethylene glycol (as synthesized) or in ethanol (purified) could be used for synthesis of Ag@TiO₂ nanoparticles with a thicker TiO₂ shell. A solution of PAA was prepared by adding 2 g of PAA (25% aqueous solution) into a mixed solvent of 1 mL of water and 8 mL ethanol, and stiffing at room temperature over 1 hour. Then 0.2 mL of the PAA solution was added into 12.5 mL of as-synthesized Ag nanoparticles in ethylene glycol (containing 0.05 mmol Ag) or into 10 mL of Ag nanoparticles in ethanol (containing less than 0.05 mmol Ag, due to loss during purification), and the solution was kept stirring for over 4 hours and sonicated for 30 minutes at room temperature. Then 1 mL of ethanol solution containing 20 μL TPO was added into the Ag nanoparticle solution, and the reaction was kept stiffing in the dark.

Characterization of nanoparticles. TEM observations of synthesized nanostructures (TiO₂, Ag and Ag@TiO₂) were performed using JEOL 200CX, JEOL 2011 and JEOL 2010F TEMs with accelerating voltage of 200 kV. The optical absorption spectroscopy measurements were performed using Beckman Coulter DU800 UV-VIS spectrophotometer. Films 1 μm thick of TiO₂ nanoparticles, or of TiO₂ nanoparticles combined with Ag@TiO₂ nanoparticles, on 2.5×2.5 cm² fused silica wafers were used for thin-film optical absorption measurements. The films were prepared by spin coating (Specialty Coating Systems, 6800 spin coater) and followed by annealing treatment at 500° C. for 15 minutes. Then the film thickness was measured using a Dektak 150 surface profiler. These films were immersed into 0.1 mM ruthenium dye solution (volume ratio of acetonitrile to tert-butanol is 1:1) and kept at room temperature for 12 hours. Then the dyed films were immersed in acetonitrile for 5 minutes to remove non-adsorbed dye.

Fabrication of DSSCs. The fabrication of the 1.5 μm-thick photoanodes of both TiO₂-only DSSCs and plasmon-enhanced DSSCs was performed by spin coating, the same method used for preparing the thin films for optical absorption measurement. For TiO₂-only DSSCs with photoanode thickness larger than 1.5 μm, the fabrication was carried out using the procedure described previously¹³. The photoanodes incorporated with Ag@TiO₂ nanoparticles were fabricated with a modified procedure. The different amounts of Ag@TiO₂ nanoparticles in ethanol solution (Ag to TiO₂ ratio from 0.02 to 1.2 wt %) were mixed with TiO₂ paste (mixture of TiO₂ nanoparticles, ethyl celluloses and terpinol), followed by stiffing and sonicating. Then ethanol was removed by a rotary evaporator. After the paste incorporated with Ag@TiO₂ nanoparticles was formed, the fabrication procedure of the photoanodes of plasmon-enhanced DSSCs was the same as that of the TiO₂-only DSSCs. The photoanodes of TiO₂-only and those incorporated with Ag@ TiO₂ were immersed into N3 dye solution and kept at room temperature for 24 hours. Then dyed films were immersed in acetonitrile for 5 min to remove non-adsorbed dye.

Characterization of DSSCs. Photovoltaic measurements were performed under illumination generated by an AM 1.5 solar simulator (Photo Emission Tech.). The power of the simulated light was calibrated to 100 mW/cm² by using a reference Si photodiode with a powermeter (1835-C, Newport) and a reference Si solar cell in order to reduce the mismatch between the simulated light and AM 1.5. The J-V curves were obtained by applying an external bias to the cell and measuring the generated photocurrent with a Keithley model 2400 digital source meter. The voltage step and delay time of photocurrent were 10 mV and 40 ms, respectively. A black tape mask was attached to the device in order to prevent irradiations from scattered light. The IPCE spectra were obtained using a computer-controlled system (Mode QEX7, PV Measurements Inc.) with a 150 W xenon lamp light source, a monochromator equipped with two 1200 g/mm diffraction gratings. The incident photon flux was determined using a calibrated silicon photodiode. Measurements were performed in a short-circuit condition, while the cell was under background illumination from a bias light of 50 mW/cm².

Results and Discussion. Structure and mechanism for the conventional and plasmon-enhanced DSSCs is illustrated in FIGS. 3A-3D. In the conventional DSSCs (FIGS. 3A and 3C), the dyes absorb incident light and generate electrons in excited states, which inject into the TiO₂ nanoparticles. The dye molecules are regenerated by electrons transferred from iodide. The regenerative cycle is completed by reducing triiodide to iodide at the Pt cathode. The electrons in TiO₂ diffuse to the current collector (fluorine-doped tin oxide, FTO). In the plasmon-enhanced DSSCs, the LSP arising from Ag@TiO₂ nanoparticles increases dye absorption, allowing the thickness of photoanode to be decreased for a given level of light absorption. By decreasing the thickness of photoanode, less materials were required, and both recombination and back reaction of photo-carriers was reduced. Reducing recombination and back reactions in turn improved the electron collection efficiency and thus overall device performance. The oxide in the plasmon-forming nanoparticle reduced the recombination and back reaction of electrons on the surface of metal nanoparticles by providing an energy barrier between metal and dye/electrolyte, as illustrated in FIG. 3E. In this situation, electrons produced by light absorption can be collected and contribute to device operation. Compare FIG. 3F, where a metal nanoparticle without an oxide on the surface makes non-productive electron transfers from L, through the TiO₂ and the metal nanoparticles, and ultimately reducing I₃⁻. The situation in FIG. 3F results in light absorption without electron collection. The oxide layer can also protects metal nanoparticles from etching by the electrolyte.

Geometric design and synthesis of core-shell nanostructure of Ag@TiO₂. According to theory, the induced electric field of the surface plasmon of a metal nanoparticle strongly depends on the radial distance, r, from the nanoparticle^{33, 34}:

$${E}_{out} ( r ) = {E}_{o} \hat{z} - [ \frac{{ɛ}_{in} - {ɛ}_{out}}{{ɛ}_{in} + 2 {ɛ}_{out}} ] {a}^{3} {E}_{0} [ \frac{\hat{z}}{{r}^{3}} - \frac{3 z}{{r}^{5}} r ] , \qquad ( 1 )$$

where E₀, and Eₒᵤₜ are the electric field of incident light and the electric field outside the metal nanoparticle; εᵢₙ and εₒᵤₜ are the dielectric constant of the metal nanoparticle and that of the external environment; a is the radius of a spherical metal nanoparticle. The surface plasmon induced electric field decreases quickly with increasing distance from the metal nanoparticle. Therefore, a thinner shell corresponds to a stronger electric field induced by LSP on or close to the surface of a core-shell nanoparticle. Accordingly, nanoparticles with a thinner shell can promote absorption enhancement of the nearby dye molecules to a greater extent than nanoparticles with a thicker shell.

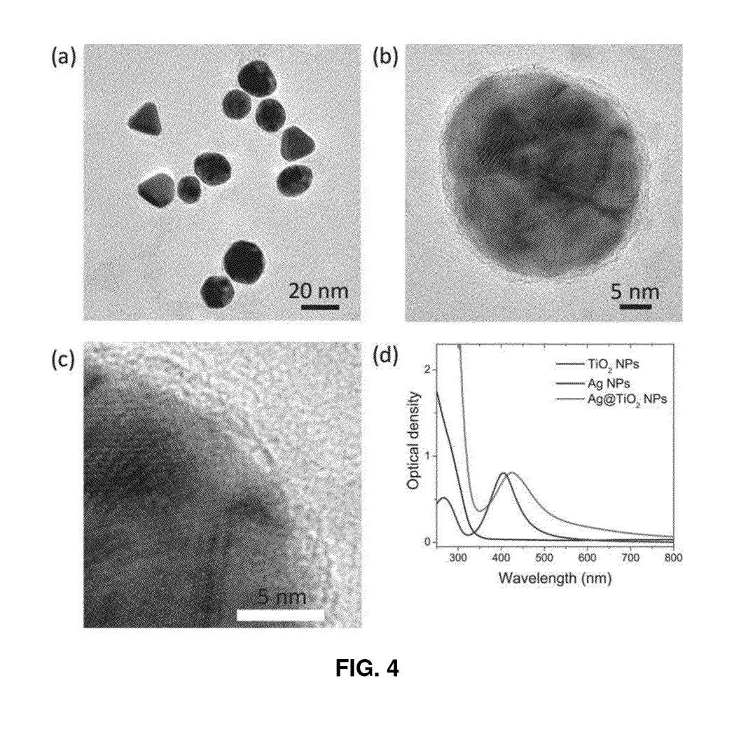

In addition, LSP plays a dominant role when the nanoparticle size is much smaller than the wavelength of incident light. This is because larger metal nanoparticles scatter light to a greater degree. Therefore, the core-shell nanostructure with a small metal core and a thin oxide shell, e.g., Ag@TiO₂, was chosen to maximize the effects of LSP on optical absorption of dye molecules and the performance of DSSCs. A two-step chemical method was used to prepare Ag@TiO₂ nanoparticles, forming Ag nanoparticles at 120° C. and forming TiO₂ shells at room temperature (see above). FIG. 4A shows the transmission electron microscope (TEM) image of Ag@TiO₂ nanoparticles and FIGS. 4B-4C show high-resolution TEM (HRTEM) images of an individual Ag@TiO₂ nanoparticle. FIGS. 4B-4C revealed the lattice fringes of Ag crystalline structure and an amorphous TiO₂ shell about 2 nm thick. The formation of Ag@TiO₂ nanostructure was also confirmed by optical absorption spectroscopy (FIG. 4D). The absorption peak from the surface plasmon resonance shifted from 403 nm for uncoated Ag nanoparticles, to a longer wavelength of 421 nm in Ag@TiO₂, because of the higher dielectric constant of amorphous TiO₂ surrounding the Ag nanoparticles than that of polyvinylpyrrolidone (PVP).

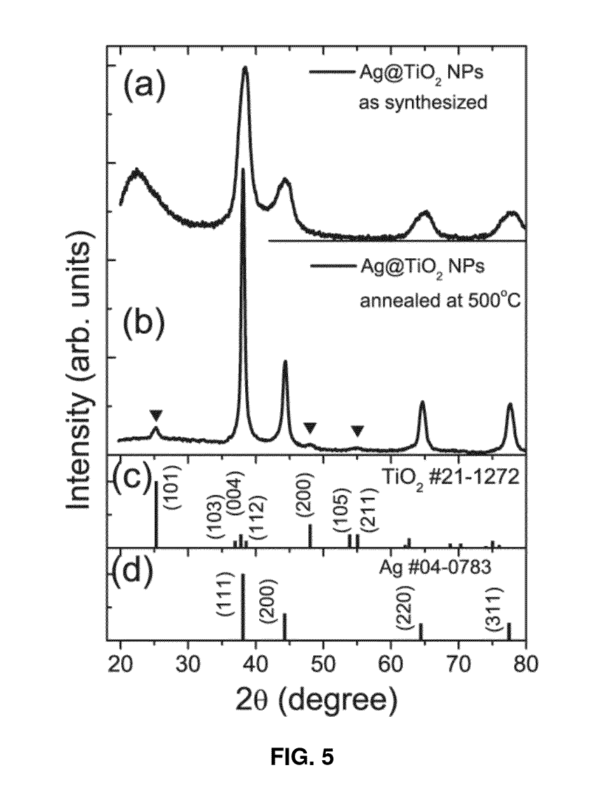

To investigate the stability of Ag@TiO₂ nanoparticles during device fabrication, the structure of the core-shell nanoparticles was examined before and after the annealing process through x-ray diffraction (XRD). FIG. 5 shows XRD patterns of Ag@TiO₂ nanoparticles as-synthesized and annealed at 500° C. For the core-shell nanoparticles as-synthesized at room temperature, the diffraction patterns from (111), (200), (220) and (311) planes of cubic structured Ag nanoparticles were clearly seen, while a broad peak at 22.4° was ascribed to the X-ray scattering from the amorphous structured TiO₂ shells. After annealing, the broad amorphous peak disappeared; while the diffraction patterns from (101), (200), (105) and (211) planes of anatase structured TiO₂ shells were observed. The crystallinity of the Ag nanoparticles was also improved by annealing, observed by both XRD and HRTEM. It was considered that the shell layer protects the Ag cores from reacting with the environment or aggregating to form larger particles during the annealing process. In addition, the shell layer was also considered to protect the Ag cores from corrosion by the electrolyte during solar cell operation.

Effect of LSP on the optical absorption of dye molecule. The effect of LSP from metal nanoparticles on the absorption of ruthenium dye is investigated in both solution and thin film.

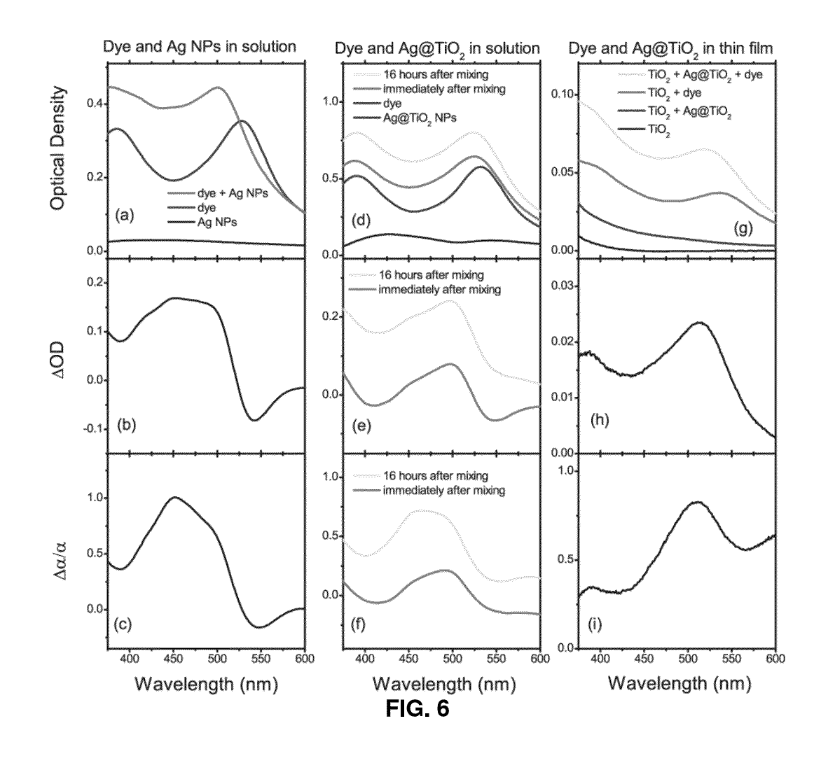

The LSP effect in solution simulated the effect in plasmon-enhanced DSSC, and the concentrations of nanoparticles and dyes could be precisely controlled. As shown in FIGS. 6A-6C, the absorption of dye increased with the presence of Ag nanoparticles in solution, and the absorption peak position shifted from 530 nm to shorter wavelength of 510 nm (FIG. 6A). The maximum relative enhancement of dye absorption occurred at 450 nm (FIG. 6C), close to the LSP resonance peak of Ag nanoparticles around 403 nm instead of the dye absorption peak at 535 nm, which suggested that the increase of dye absorption mainly arose from LSP of Ag nanoparticles. FIGS. 6D-6F show that the dye absorption in solution could also be enhanced by incorporating Ag@TiO₂ nanoparticles. Moreover, this enhancement of dye absorption increased with time after mixing dye and core-shell NPs (FIG. 6D), which could be the effect of the dye molecules adsorbing on the surface of TiO₂ shell. As the time after mixing increased, the number of dye molecules adsorbed on the Ag@TiO₂ NPs increased, reducing the average distance between dye molecules and Ag cores, thus further enhancing the dye absorption. This time-dependent (i.e., dye-to-nanoparticle distance-dependent) behavior of absorption enhancement was consistent with the concept of using a thin shell to maximize the LSP effect.

In addition, the adsorption of dye on Ag@TiO₂ in solution was similar to that in the thin films where the dye molecules are adsorbed on or near the surface of Ag@TiO₂ nanoparticles. In order to study the LSP effect on the absorption of dye molecules in meso-porous TiO₂ thin films, films 1 μm thick were prepared by spin-coating either TiO₂ nanoparticles or TiO₂ nanoparticles blended with Ag@TiO₂ nanoparticles (Ag:TiO₂=0.2 wt %) and annealed at 500° C. (see above). Compared to the dyed TiO₂ film, there was an increase of absorption for the film incorporated with Ag@TiO₂ nanoparticles (FIG. 6G), and the enhancement was similar to that in the solution (FIG. 6I). It also agreed with the previously reported observations on plasmon-enhanced dye absorption.^{24, 25, 27, 28, 32} The increase of absorption of dye molecules could be attributed to the interaction of dye molecular dipole and enhanced electric field surrounding the nanoparticles, together with the increase of light scattering also induced by the LSP which increased the optical path.

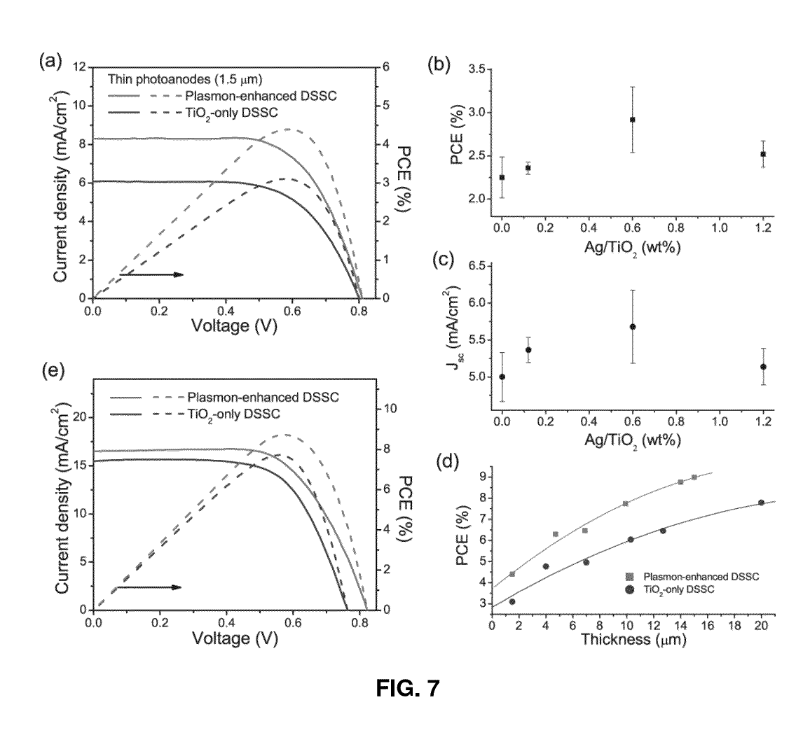

Effect of LSP on the performance of DSSC. To investigate the effect of LSP on device performance, plasmon-enhanced DSSCs were compared to standard DSSCs with only TiO₂ NPs as photoanodes. The TiO₂-only DSSCs were fabricated using conventional methods,¹³ while the Ag@TiO₂ nanoparticles were incorporated into TiO₂ paste (at 0.02 to 1.2 wt %) to fabricate the plasmon-enhanced DSSCs (see above). FIG. 7A shows the photocurrent density-voltage characteristics (J-V curves) of the most efficient plasmon-enhanced DSSC and TiO₂-only DSSC with the same photoanode thickness of 1.5 μm. The TiO₂-only DSSC showed a PCE (η) of 3.1%; whereas the plasmon-enhanced DSSC with Ag@TiO₂ nanoparticles exhibited a PCE of 4.4% (an increase of 42%). Compared with the TiO₂-only DSSC, the fill factor (FF) and open-circuit voltage (V_{OC}) of the plasmon-enhanced DSSC were close; while the short-circuit current density (J_{SC}) significantly increased by 37%, from 6.07 mA/cm² to 8.31 mA/cm². Since

η=J_{SC}·V_{OC}·FF/P₀

where P₀ is the intensity of incident light, the improvement of PCE in plasmon-enhanced DSSC is mainly due to the increased photocurrent corresponding to enhanced dye absorption by LSP. The effect of the concentration of Ag@TiO₂ on device performance was also investigated. FIGS. 7B-7C show the averaged PCE and J_{SC} changing with concentration of Ag@TiO₂ nanoparticles. As the concentration of Ag@TiO₂ increased from 0 to 0.6 wt %, both J_{SC} and PCE increased monotonically. As the concentration of Ag@TiO₂ further increased, PCE began to decrease, probably due to the increased trapping of photo-generated electrons by Ag, and increased light absorption of Ag nanoparticles which transformed part of the incident solar power into heat. Therefore, through enhancing the light absorption and photocurrent, the device performance of DSSCs has been improved by LSP from Ag@TiO₂ nanoparticles.

For practical DSSCs, thicker photoanodes are required to absorb more light. By using LSP, the thickness of photoanodes can be reduced while maintaining the optical absorption of DSSC. As shown in FIG. 7D, the PCE of DSSCs increased with the thickness for both conventional and plasmon-enhanced DSSCs, but it increased faster with the presence of Ag@Ti02 nanoparticles in the photoanode. For the devices with the same thickness, the PCE of the plasmon-enhanced DSSC was higher than that of TiO₂-only DSSC. In addition, to achieve the same PCE, the photoanode thickness of the plasmon-enhanced DSSC was much thinner than that of TiO₂-only DSSC. For instance, it was observed that the plasmon-enhanced DSSC with 5 μm thick photoanode and TiO₂-only DSSC with 13 μm thick photoanode possessed the same PCE of 6.5%. Thus, in this instance, 62% less materials could be used for device fabrication without affecting the device performance.

Electron collection is also an important factor to be considered in addition to light harvesting, since light absorption in practical devices approaches unity with thicker photoanodes. However, the carrier collection efficiency is decreased in thicker photoanodes due to the longer distance that electrons must travel. Because a plasmon-enhanced device can provide the same level of light absorption in a thinner photoanode, it can have more efficient electron collection than a similar device with that same level of light absorption. This results in better overall device performance.

As shown in FIG. 7E, the plasmon-enhanced DSSC achieved a PCE of 9.0% with a 15 μm thick photoanode, compared to the TiO₂-only DSSC only reached a PCE of 7.8% with a 20 μm thick photoanode. Therefore, by introducing Ag@TiO₂ nanoparticles into the TiO₂ photoanode, the PCE of the DSSC was improved by 15% while the photoanode thickness was decreased by 25%. Considering the near unity optical absorption for the photoanodes of both plasmon-enhanced and TiO₂-only DSSCs, the improved PCE mostly arose from increased electron collection efficiency by decreased distance for electron diffusion. In addition, the uniform plasmonic geometry employed enhanced the absorption throughout the photoanode, whereas the metal nanoparticles from previous works were located either on the current collector,²³⁻²⁸ or the counter electrode,²⁹ where LSP only affected the thin layer close to the metal nanoparticles.

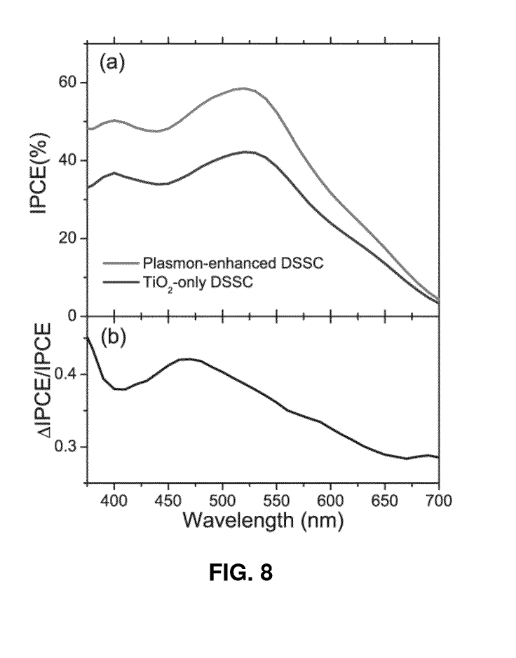

To investigate the effect of LSP on the spectral response of the solar cells, the incident photon-to-current efficiency (IPCE) was measured (FIG. 8). The IPCE is the product of the light harvesting efficiency, electron injection efficiency and electron collection efficiency. Increasing light absorption will directly improve light harvesting and the IPCE, if electron injection and collection are not affected. As shown in FIG. 8A, the shape of the IPCE spectrum from the TiO₂-only device closely matched the shape of optical absorption of the dye molecules in the thin film. In contrast, the IPCE spectrum from the plasmon-enhanced device increased over the whole wavelength range. Moreover, the enhancement was most significant in the range of 400-500 nm with a peak around 460 nm (FIG. 8B). The similarity between IPCE enhancement of DSSC and the absorption enhancement of the thin film indicated (see FIGS. 6G-6I) that the LSP from core-shell nanoparticles improved the device performance through increased dye absorption.

### REFERENCES

Each of the following references is hereby incorporated by reference in its entirety.

1. O'Regan, B.; Grätzel, M., A Low-Cost, High-Efficiency Solar Cell Based on Dye-Sensitized Colloidal TiO₂ Films. Nature 1991, 353, 737-740.

2. Nazeeruddin, M. K.; Kay, A.; Rodicio, I.; Humphry-Baker, R.; Mueller, E.; Liska, P.; Vlachopoulos, N.; Graetzel, M., Conversion of Light to Electricity by Cis-X₂bis(2,2′-bipyridyl-4,4′-dicarboxylate)ruthenium(II) Charge-Transfer Sensitizers (X═Cl⁻, Br⁻, I⁻, CN⁻, and SCN⁻) on Nanocrystalline Titanium Dioxide Electrodes. J. Am. Chem. Soc. 1993, 115, 6382-6390.

3. Grätzel, M., Photoelectrochemical Cells. Nature 2001, 414, 338-344.

4. Grätzel, M., Dye-Sensitized Solar Cells. J. Photochem. Photobiol. A: Photochem. Rev. 2003, 4, 145-153.

5. Chen, C.-Y.; Wang, M.; Li, J.-Y.; Pootrakulchote, N.; Alibabaei, L.; Ngoc-le, C.-h.; Decoppet, J.-D.; Tsai, J.-H.; Grätzel, C.; Wu, C.-G.; Zakeeruddin, S. M.; Grätzel, M., Highly Efficient Light-Harvesting Ruthenium Sensitizer for Thin-Film Dye-Sensitized Solar Cells. ACS Nano 2009, 3, 3103-3109.

6. Law, M.; Greene, L. E.; Johnson, J. C.; Saykally, R.; Yang, P., Nanowire Dye-Sensitized Solar Cells. Nature Mater. 2005, 4, 455-459.

7. Varghese, O. K.; Paulose, M.; Grimes, C. A., Long Vertically Aligned Titania Nanotubes on Transparent Conducting Oxide for Highly Efficient Solar Cells. Nature Nanotech. 2009, 4, 592-597.

8. Wang, P.; Zakeeruddin, S. M.; Moser, J. E.; Nazeeruddin, M. K.; Sekiguchi, T.; Grätzel, M., A Stable Quasi-Solid-State Dye-Sensitized Solar Cell with an Amphiphilic Ruthenium Sensitizer and Polymer Gel Electrolyte. Nature Mater. 2003, 2, 402-407.

9. Nazeeruddin, M. K.; Bessho, T.; Cevey, L.; Ito, S.; Klein, C.; De Angelis, F.; Fantacci, S.; Comte, P.; Liska, P.; Imai, H.; Graetzel, M., A High Molar Extinction Coefficient Charge Transfer Sensitizer and its Application in Dye-Sensitized Solar Cell. J. Photochem. Photobiol. A: Chem. 2007, 185, 331-337.

10. Grätzel, M., Recent Advances in Sensitized Mesoscopic Solar Cells. Acc. Chem. Res. 2009, 42, 1788-1798.

11. Mora-Seró, I. n.; Bisquert, J., Breakthroughs in the Development of Semiconductor-Sensitized Solar Cells. J. Phys. Chem. Lett. 2010, 1, 3046-3052.

12. Sambur, J. B.; Novet, T.; Parkinson, B. A., Multiple Exciton Collection in a Sensitized Photovoltaic System. Science 2010, 330, 63-66.

13. Dang, X.; Yi, H.; Ham, M.-H.; Qi, J.; Yun, D. S.; Ladewski, R.; Strano, M. S.; Hammond, P. T.; Belcher, A. M., Virus-Templated Self-Assembled Single-Walled Carbon Nanotubes for Highly Efficient Electron Collection in Photovoltaic Devices. Nature Nanotech. 2011, 6, 377-384.

14. Atwater, H. A.; Polman, A., Plasmonics for Improved Photovoltaic Devices. Nature Mater. 2010, 9, 205-213.

15. Stuart, H. R.; Hall, D. G., Island Size Effects in Nanoparticle-Enhanced Photodetectors. Appl. Phys. Lett. 1998, 73, 3815-3817.

16. Schaadt, D. M.; Feng, B.; Yu, E. T., Enhanced Semiconductor Optical Absorption via Surface Plasmon Excitation in Metal Nanoparticles. Appl. Phys. Lett. 2005, 86, 063106-3.

17. Derkacs, D.; Lim, S. H.; Matheu, P.; Mar, W.; Yu, E. T., Improved Performance of Amorphous Silicon Solar Cells via Scattering from Surface Plasmon Polaritons in Nearby Metallic Nanoparticles. Appl. Phys. Lett. 2006, 89, 093103-3.

18. Pillai, S.; Catchpole, K. R.; Trupke, T.; Green, M. A., Surface Plasmon Enhanced Silicon Solar Cells. J. Appl. Phys. 2007, 101, 093105-8.

19. Wu, J.-L.; Chen, F.-C.; Hsiao, Y.-S.; Chien, F.-C.; Chen, P.; Kuo, C.-H.; Huang, M. H.; Hsu, C.-S., Surface Plasmonic Effects of Metallic Nanoparticles on the Performance of Polymer Bulk Heterojunction Solar Cells. ACS Nano 2011, 5, 959-967.

20. Westphalen, M.; Kreibig, U.; Rostalski, J.; Liith, H.; Meissner, D., Metal Cluster Enhanced Organic Solar Cells. Sol. Energy Mater. Sol. Cells 2000, 61, 97-105.

21. Rand, B. P.; Peumans, P.; Forrest, S. R., Long-Range Absorption Enhancement in Organic Tandem Thin-Film Solar Cells Containing Silver Nanoclusters. J. Appl. Phys. 2004, 96, 7519-7526.

22. Morfa, A. J.; Rowlen, K. L.; Reilly, T. H.; Iii; Romero, M. J.; van de Lagemaat, J., Plasmon-Enhanced Solar Energy Conversion in Organic Bulk Heterojunction Photovoltaics.

Appl. Phys. Lett. 2008, 92, 013504-3.

23. Konda, R. B.; Mundle, R.; Mustafa, H.; Bamiduro, O.; Pradhan, A. K.; Roy, U. N.; Cui, Y.; Burger, A., Surface Plasmon Excitation via Au Nanoparticles in n-CdSe/p-Si Heterojunction Diodes. Appl. Phys. Lett. 2007, 91, 191111-3.

24. Ihara, M.; Tanaka, K.; Sakaki, K.; Honma, I.; Yamada, K., Enhancement of the Absorption Coefficient of Cis-(NCS)₂ Bis(2,2′-bipyridyl-4,4′-dicarboxylate)ruthenium(II) Dye in Dye-Sensitized Solar Cells by a Silver Island Film. J. Phys. Chem. B 1997, 101, 5153-5157.

25. Ishikawa, K.; Wen, C. J.; Yamada, K.; Okubo, T., The Photocurrent of Dye-Sensitized Solar Cells Enhanced by the Surface Plasmon Resonance. J. Chem. Eng. Jpn. 2004, 37, 645-649.

26. Hagglund, C.; Zach, M.; Kasemo, B., Enhanced Charge Carrier Generation in Dye Sensitized Solar Cells by Nanoparticle Plasmons. Appl. Phys. Lett. 2008, 92, 013113-3.

27. Standridge, S. D.; Schatz, G. C.; Hupp, J. T., Toward Plasmonic Solar Cells: Protection of Silver Nanoparticles via Atomic Layer Deposition of TiO₂. Langmuir 2009, 25, 2596-2600.

28. Standridge, S. D.; Schatz, G. C.; Hupp, J. T., Distance Dependence of Plasmon-Enhanced Photocurrent in Dye-Sensitized Solar Cells. J. Am. Chem. Soc. 2009, 131, 8407-8409.

29. Zhao, G.; Kozuka, H.; Yoko, T., Effects of the Incorporation of Silver and Gold Nanoparticles on the Photoanodic Properties of Rose Bengal Sensitized TiO₂ Film Electrodes Prepared by Sol-Gel Method. Sol. Energy Mater. Sol. Cells 1997, 46, 219-231.

30. Wen, C.; Ishikawa, K.; Kishima, M.; Yamada, K., Effects of Silver Particles on the Photovoltaic Properties of Dye-Sensitized TiO₂ Thin Films. Sol. Energy Mater. Sol. Cells 2000, 61, 339-351.

31. Ding, I. K.; Zhu, J.; Cai, W.; Moon, S.-J.; Cai, N.; Wang, P.; Zakeeruddin, S. M.; Grätzel, M.; Brongersma, M. L.; Cui, Y.; McGehee, M. D., Plasmonic Back Reflectors: Plasmonic Dye-Sensitized Solar Cells. Adv. Energy Mater. 2011, 1, 51-51.

32. Brown, M. D.; Suteewong, T.; Kumar, R. S. S.; D+Innocenzo, V.; Petrozza, A.; Lee, M. M.; Wiesner, U.; Snaith, H. J., Plasmonic Dye-Sensitized Solar Cells Using Core-Shell Metal-Insulator Nanoparticles. Nano Lett. 2010, 11, 438-445.

33. Willets, K. A.; Van Duyne, R. P., Localized Surface Plasmon Resonance

Spectroscopy and Sensing. Annu. Rev. Phys. Chem. 2007, 58, 267-297.

34. Kelly, K. L.; Coronado, E.; Zhao, L. L.; Schatz, G. C., The Optical Properties of Metal Nanoparticles: The Influence of Size, Shape, and Dielectric Environment. J. Phys. Chem. B 2002, 107, 668-677.

Other embodiments are within the scope of the following claims.

What is claimed is:

1. A dye-sensitized solar cell comprising a photoanode including a plurality of TiO₂ nanoparticles and a plurality of a plasmon-forming nanostructures, wherein each plasmon-forming nanostructure includes a metal nanoparticle and a semiconducting oxide on a surface of the metal nanoparticle.

2. The dye-sensitized solar cell of claim 1, wherein each plasmon-forming nanostructure includes a core including the metal nanoparticle.

3. The dye-sensitized solar cell of claim 2, wherein each plasmon-forming nanostructure includes a coating on the core, wherein the coating includes the semiconducting oxide.

4. The dye-sensitized solar cell of claim 3, wherein the metal nanoparticle includes silver or gold.

5. The dye-sensitized solar cell of claim 4, wherein the semiconducting oxide includes TiO₂.

6. The dye-sensitized solar cell of claim 5, wherein the core has a diameter of no greater than 50 nm.

7. The dye-sensitized solar cell of claim 6, wherein the coating has a thickness of no greater than 5 nm.

8. The dye-sensitized solar cell of claim 1, wherein the plurality of plasmon-forming nanostructures is interspersed with the plurality of TiO₂ nanoparticles.

9. The dye-sensitized solar cell of claim 8, wherein the plasmon-forming nanostructures are 0.01 wt % to 2.5 wt % of the total nanoparticles in the photoanode.

10. A method of generating solar power, comprising illuminating a dye-sensitized solar cell including a photoanode including a plurality of TiO₂ nanoparticles and a plurality of a plasmon-forming nanostructures, wherein each plasmon-forming nanostructure includes a metal nanoparticle and a semiconducting oxide on a surface of the metal nanoparticle.

11. The method of claim 10, wherein each plasmon-forming nanostructure includes a core including the metal nanoparticle.

12. The method of claim 11, wherein each plasmon-forming nanostructure includes a coating on the core, wherein the coating includes the semiconducting oxide.

13. The method of claim 12, wherein the metal nanoparticle includes silver or gold.

14. The method of claim 13, wherein the semiconducting oxide includes TiO₂.

15. The method of claim 14, wherein the core has a diameter of no greater than 50 nm.

16. The method of claim 15, wherein the coating has a thickness of no greater than 5 nm.

17. The method of claim 10, wherein the plurality of a plasmon-forming nanostructures is interspersed with the plurality of TiO₂ nanoparticles.

18. The method of claim 17, wherein the plasmon-forming nanostructures are 0.01 wt % to 2.5 wt % of the total nanoparticles in the photoanode.

19. A method of making a dye-sensitized solar cell comprising forming a photoanode including a plurality of TiO₂ nanoparticles and a plurality of a plasmon-forming nanostructures, wherein each plasmon-forming nanostructure includes a metal nanoparticle and a semiconducting oxide on a surface of the metal nanoparticle.

20. The method of claim 19, wherein forming the photoanode includes depositing the plurality of plasmon-forming nanostructures on a substrate.

21. The method of claim 20, wherein forming the photoanode includes mixing the plurality of TiO₂ nanoparticles with the plurality of plasmon-forming nanostructures prior to depositing.

22. The method of claim 19, wherein each plasmon-forming nanostructure includes a core including the metal nanoparticle.

23. The method of claim 22, wherein each plasmon-forming nanostructure includes a coating on the core, wherein the coating includes the semiconducting oxide.

24. The method of claim 23, wherein the metal nanoparticle includes silver or gold.

25. The method of claim 24, wherein the semiconducting oxide includes TiO₂.

26. The method of claim 25, wherein the core has a diameter of no greater than 50 nm.

27. The method of claim 26, wherein the coating has a thickness of no greater than 5 nm.

28. The method of claim 19, wherein the plurality of plasmon-forming nanostructures is interspersed with the plurality of TiO₂ nanoparticles.

29. The method of claim 28, wherein the plasmon-forming nanostructures are 0.01 wt % to 2.5 wt % of the total nanoparticles in the photoanode.
